(19) United States
(12) Patent Application Publication
(10) Pub. No.: US 2025/0372483 A1
(43) Pub. Date: Dec. 4, 2025

(54) SEMICONDUCTOR DEVICES INCLUDING SELF-ALIGNED BACKSIDE GATE CONTACT STRUCTURES AND METHODS FOR FABRICATING THE SAME

(71) Applicant: Samsung Electronics Co., Ltd., Suwon-si (KR)

(72) Inventors: Joongsuk Oh, Watervliet, NY (US); Kang-Min Jung, Clifton Park, NY (US); Byounghoon Kim, Rexford, NY (US); Kang-ill Seo, Springfield, VA (US)

(21) Appl. No.: 18/953,713

(22) Filed: Nov. 20, 2024

Related U.S. Application Data
(60) Provisional application No. 63/653,581, filed on May 30, 2024.

(51) Int. Cl. H01L 23/48; H01L 21/768; H01L 23/528; H01L 29/06; H01L 29/423; H01L 29/66; H01L 29/775; H01L 29/786

(52) U.S. Cl. CPC H01L 23/481; H01L 21/76898; H01L 23/5286; H10D 30/014; H10D 30/43; H10D 30/6735; H10D 30/6757; H10D 62/121

(57) ABSTRACT

A method of fabricating a semiconductor device includes forming capping patterns that are spaced apart in a first direction on a second side of a semiconductor structure, and forming channel structures that are spaced apart in the first direction on a first side of the semiconductor structure. A bottom portion of a gate structure extends between first and second channel structures among the channel structures. The first and second channel structures vertically overlap first and second capping patterns among the capping patterns, respectively. The method further includes forming a backside gate contact structure that contacts the bottom portion of the gate structure and is aligned based on the first and second capping patterns.

### RELATED APPLICATIONS

The present application claims the benefit of U.S. Provisional Patent Application Ser. No. 63/653,581, entitled “SELF-ALIGNED BACKSIDE GATE CONTACT STRUCTURE,” filed on May 30, 2024, with the United States Patent and Trademark Office, the disclosure of which is hereby incorporated by reference herein in its entirety.

### TECHNICAL FIELD

The present disclosure generally relates to the field of semiconductor devices and, more particularly, to semiconductor devices having backside contacts.

### BACKGROUND

Integrated circuit (IC) devices, chips, and/or blocks may receive power and data signals from one or more external sources (e.g., a power source and a data source). Some IC devices may receive power and data signals via frontside conductive structures, which may provide power distribution networks (PDNs). For example, an IC device may include an frontside power distribution network (FSPDN) having one or more components that are formed during back-end-of-line (BEOL) processes, and conductive structures for data signals may be on the same side of an IC device as the FSPDN. IC devices may include various transistor structures, including, for example, two-dimensional (2D) planar structures, fin field-effect transistors (FinFETs), gate-all-around transistors, multi-bridge channel FETs (MBCFETs™), and stacked transistors (e.g., three-dimensional (3D) stacked transistors).

More recently, backside PDNs (BSPDNs), in which a backside of an IC device is used as a PDN, have also been developed. In a BSPDN structure, a power rail may be formed on the backside of a semiconductor chip, IC device, or wafer (generally referred to herein as a semiconductor device), rather than on the front side. As such, the power rail may be on a side of the semiconductor structure (e.g., a side of a substrate of the IC device) that is opposite from the active components (e.g., transistors) of the IC device. Moreover, conductive structures for data signals may be on the frontside of the semiconductor device, and thus the BSPDN and the conductive structures for the data signals may be on opposite sides of the semiconductor device. BSPDN structures may improve power rail effectiveness, voltage drop (i.e., IR drop), high power delivery performance, and further scaling of standard cell height.

### SUMMARY

According to some embodiments, a semiconductor device includes first and second channel structures that are spaced apart in a first direction. A gate structure extends in the first direction, where a bottom portion of the gate structure extends between the first and second channel structures. A backside gate contact structure contacts the bottom portion of the gate structure. The backside gate contact structure includes a lower contact structure and an upper contact structure between the lower contact structure and the gate structure, and respective side surfaces of the upper contact structure and the lower contact structure have different slopes.

In some embodiments, the respective side surfaces of the upper contact structure and the lower contact structure may define a step difference therebetween.

In some embodiments, a first slope of the side surface of the upper contact structure may be less than a second slope of the side surface of the lower contact structure.

In some embodiments, the backside gate contact structure may extend through a substrate having the first and second channel structures on a first side thereof. The backside gate contact structure may extend into the substrate from a second side of the semiconductor structure, which is opposite the first side, to contact the gate structure.

In some embodiments, an isolation pattern may be provided on the first side of the substrate between the first and second channel structures. The backside gate contact structure may extend through the isolation pattern to contact the gate structure, and the step difference may be spaced apart from the isolation pattern in a second direction that is perpendicular to the first direction.

In some embodiments, the backside gate contact structure may electrically connect a backside power distribution network structure on the second side of the substrate to the gate structure on the first side of the substrate.

In some embodiments, each of the first and second channel structures may include a plurality of nanosheet structures that are stacked on the first side of the substrate.

According to some embodiments, a method of fabricating a semiconductor device includes forming channel structures that are spaced apart in a first direction on a first side of a semiconductor structure, and forming a gate structure that extends in the first direction on the first side of the semiconductor structure, where a bottom portion of the gate structure extends between first and second channel structures among the channel structures. The method further includes forming capping patterns that are spaced apart in the first direction on a second side of the semiconductor structure that is opposite the first side, where first and second capping patterns among the capping patterns vertically overlap the first and second channel structures, respectively, and forming a backside gate contact structure that contacts the bottom portion of the gate structure and is aligned based on the first and second capping patterns.

In some embodiments, opposing side surfaces of the first and second capping patterns are substantially aligned with opposing side surfaces of the first and second channel structures, respectively, in a second direction that is perpendicular to the first direction.

In some embodiments, forming the backside gate contact structure includes forming a gate placeholder element that extends into the second side of the semiconductor structure and contacts the bottom portion of the gate structure between the first and second channel structures.

In some embodiments, forming the gate placeholder element includes forming an opening in the second side of the semiconductor structure that extends between the first and second capping patterns and exposes the bottom portion of the gate structure between the first and second channel structures, and forming the gate placeholder element in the opening.

In some embodiments, forming the backside gate contact structure further includes removing portions of the semiconductor structure and the capping patterns thereon to expose the gate placeholder element between the first and second channel structures, forming a substrate on the gate placeholder element and the channel structures, where the channel structures are on a first side of the substrate, patterning a second side of the substrate that is opposite the first side to form a first opening therein that exposes the gate placeholder element, and replacing the gate placeholder element with the backside gate contact structure.

In some embodiments, replacing the gate placeholder element includes removing the gate placeholder element to form a second opening in the substrate that is coupled to the first opening and exposes the bottom portion of the gate structure between the first and second channel structures, and forming the backside gate contact structure in the first and second openings.

In some embodiments, respective side surfaces of the first opening and the second opening have different slopes, and the backside gate contact structure includes a lower contact structure in the first opening and an upper contact structure in the second opening between the lower contact structure and the gate structure.

In some embodiments, the respective side surfaces of the first opening and the second opening define a step difference therebetween.

In some embodiments, the method further includes forming a backside power distribution network structure on the second side of the substrate, where the backside gate contact structure electrically connects the backside power distribution network structure to the gate structure.

In some embodiments, forming the capping patterns includes patterning a stop layer material that is different from a material of the semiconductor structure to define a patterned stop layer having plurality of trenches therein that are spaced apart in the first direction, forming the semiconductor structure on the patterned stop layer, removing the patterned stop layer to expose a patterned surface on the second side of the semiconductor structure, and forming the capping patterns in the patterned surface on the second side of the semiconductor structure.

According to some embodiments, a method of fabricating a semiconductor device includes patterning a stop layer material to define a patterned stop layer having plurality of trenches therein that are spaced apart in a first direction, and forming a semiconductor structure on the patterned stop layer. The semiconductor structure includes a different material than the patterned stop layer, with a second side thereof facing the patterned stop layer. The method further includes forming channel structures that are spaced apart in the first direction on a first side of the semiconductor structure that is opposite the second side, where the channel structures vertically overlap surfaces of the patterned stop layer between the trenches therein.

In some embodiments, opposing side surfaces of the channel structures are substantially aligned with opposing sidewalls of the trenches in the patterned stop layer, respectively, in a second direction that is perpendicular to the first direction.

In some embodiments, the method further includes removing the patterned stop layer to expose a patterned surface having a plurality of second trenches therein on the second side of the semiconductor structure.

In some embodiments, opposing side surfaces of the channel structures are substantially aligned with opposing sidewalls of the second trenches in the patterned surface, respectively, in a second direction that is perpendicular to the first direction.

In some embodiments, the method further includes forming capping patterns in the patterned surface on the second side of the semiconductor structure, where opposing side surfaces of the capping patterns are substantially aligned with opposing side surfaces of the channel structures, respectively.

In some embodiments, the method further includes forming a gate structure that extends in the first direction on the first side of the semiconductor structure, where a bottom portion of the gate structure extends between first and second channel structures among the channel structures, and forming a backside gate contact structure that contacts the bottom portion of the gate structure and is aligned based on first and second capping patterns among the capping patterns.

Other devices, apparatus, and/or methods according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF THE DRAWINGS

FIG. 1 is a plan or layout view illustrating an integrated circuit device including self-aligned backside gate contact structures according to some embodiments.

FIG. 2A is a cross-sectional view taken along line II-II of FIG. 1, illustrating an integrated circuit device including self-aligned backside gate contact structures according to some embodiments.

FIG. 2B is an enlarged cross-sectional view illustrating upper and lower contact structures of the backside gate contact structure of FIG. 2A.

FIG. 2C is a cross-sectional view taken along line II-II of FIG. 1, illustrating an integrated circuit device including self-aligned backside gate contact structures according to some embodiments.

FIGS. 3A, 3B, 3C, 3D, 3E, and 3F are cross-sectional views illustrating methods of forming a patterned stop layer for fabricating self-aligned backside gate contact structures according to some embodiments.

FIGS. 4A, 4B, 4C, 4D, 4E, and 4F are cross-sectional views illustrating methods of forming capping patterns based on the patterned stop layer for fabricating self-aligned backside gate contact structures according to some embodiments.

FIGS. 5A, 5B, 5C, 5D, 5E, and 5F are cross-sectional views illustrating methods of forming gate placeholder elements that are self-aligned based on the capping patterns for fabricating self-aligned backside gate contact structures according to some embodiments.

FIGS. 6A, 6B, 6C, 6D, 6E, and 6F are cross-sectional views illustrating methods of forming self-aligned backside gate contact structures using the gate placeholder elements according to some embodiments.

FIG. 7 is a flowchart illustrating methods of forming a patterned stop layer according to some embodiments.

FIG. 8 is a flowchart illustrating methods of forming capping patterns based on the patterned stop layer according to some embodiments.

FIG. 9 is a flowchart illustrating methods of forming gate placeholder elements that are self-aligned based on the capping patterns according to some embodiments.

FIG. 10 is a flowchart illustrating methods of forming self-aligned backside gate contact structures using the gate placeholder elements according to some embodiments.

### DETAILED DESCRIPTION OF EMBODIMENTS

A BSPDN structure may include a power delivery network that includes one or more power rails in a backside of a semiconductor device. Different ways to connect from the frontside to the backside include, for example, a front via backside power rail (FV-BPR) and a direct backside contact (DBC). The DBC may be more effective in terms of process capability and dimension limitations than other ways of connecting the frontside to the backside. As contacted poly pitch (CPP) becomes smaller, however, DBCs may be more difficult to form due to patterning issues such as photo overlay and high aspect ratio etch process (which may result in voids in the DBCs).

In a DBC scheme, due to the wafer warpage and distortion, connection to a source/drain region or a gate structure may be challenging in terms of lithography overlay. Forming a frontside gate contact structure on a gate structure may be less difficult because the frontside gate contact structure may be above a channel structure and a source/drain region. However, in case of a backside contact, a contact etch process may be performed from the backside of the semiconductor structure (e.g., between the nanosheet channels, which are on the frontside), and thus, the fabrication process may be more challenging.

Pursuant to embodiments herein, semiconductor (e.g., integrated circuit) devices are provided with self-aligned backside gate contact structures. In particular embodiments, a self-aligned backside gate contact structure may be formed using a different-or varying-height (e.g., uneven) silicon germanium (SiGe) stop layer that is patterned based on locations of the channel structures on an opposite side of the semiconductor structure, corresponding capping patterns (e.g., silicon nitride (SiN) nanosheet capping patterns) that are aligned with the channel patterns based on the patterned stop layer, and a backside gate placeholder element that is self-aligned based on the capping patterns. Some examples of embodiments of the present disclosure are described in greater detail with reference to the attached figures.

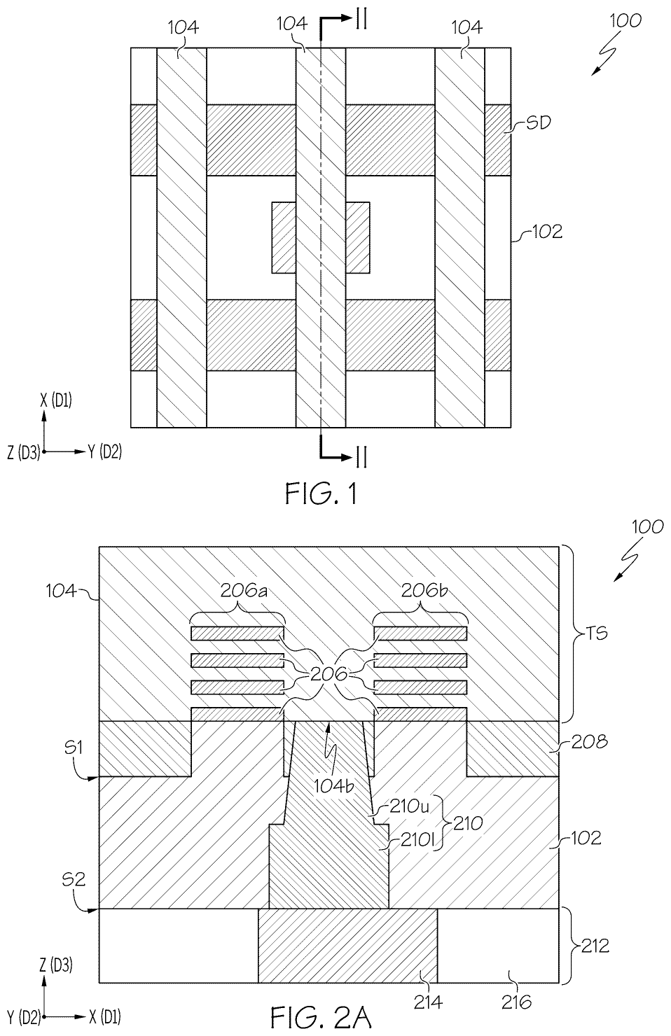

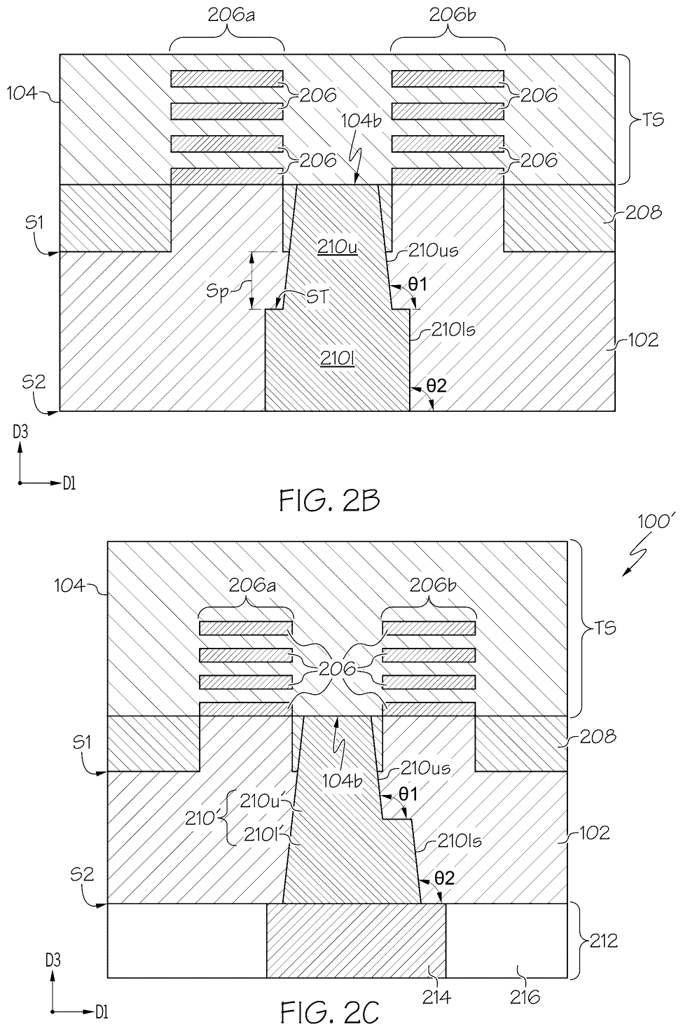

FIG. 1 is a plan or layout view illustrating an integrated circuit device 100 including self-aligned backside gate contact structures according to some embodiments. FIG. 2A is a cross-sectional view taken along line II-II of FIG. 1, illustrating an integrated circuit device 100 including self-aligned backside gate contact structures according to some embodiments.

Referring to FIGS. 1 and 2A, the integrated circuit device 100 may include a substrate 102 (also referred to as a backside insulating layer) and transistor structures TS (also referred to as transistors) on a first side (or frontside) S1 of the substrate 102. The substrate 102 may extend in a first direction D1 (also referred to as a first horizontal direction or X direction) and a second direction D2 (also referred to as a second horizontal direction or Y direction). The first direction D1 and the second direction D2 may be parallel to a surface (e.g., the frontside S1) of the substrate 120. In some embodiments, the first direction D1 may be perpendicular to the second direction D2.

In some embodiments, the substrate 102 may include or may be formed of insulating material(s), for example, silicon oxide, silicon oxynitride, silicon nitride, silicon carbonitride, silicon boron nitride and/or a low-k dielectric material. The low-k dielectric material may include, for example, fluorine-doped silicon oxide, organosilicate glass, carbon-doped oxide, porous silicon dioxide, porous organosilicate glass, spin-on organic polymeric dielectrics and/or spin-on silicon based polymeric dielectric. In some other embodiments, the substrate 102 may include or may be semiconductor material(s), for example, Si, Ge, SiGe, GaP, GaAs, SiC, SiGeC and/or InP. For example, the substrate 102 may be insulating layer(s), a bulk substrate (e.g., a bulk silicon wafer) and/or a semiconductor-on-insulator (SOI) substrate. A thickness of the substrate 102 in a third direction D3 (also referred to as a vertical direction or Z direction) may be, for example, in a range of about 50 nm to 100 nm. In some embodiments, the third direction D3 may be perpendicular to the first direction D1 and/or the second direction D2. The third direction D3 may be perpendicular to the surface (e.g., the frontside S1) of the substrate 102.

Each of the transistor structures TS may include a gate structure 104 and a channel structure 206 that extends between source/drain regions SD. In some embodiments, each of the transistor structures TS may include multiple channel structures 206 stacked in the third direction D3, and the channel structures 206 may be spaced apart from each other in the third direction D3. For example, the transistor structures TS may be nanosheet transistors that include a stack of nanosheet layers in each channel structures 206. A gate insulator (not shown) may extend between the gate structures 104 and the channel structures 206. More particularly, the gate insulator may contact and physically separate the gate structure 104 and the channel structure 206 (including nanosheets thereof).

Each of the transistor structures TS may also include a pair of source/drain regions SD that may be spaced apart from each other in the second direction D2. The gate structure 104 may be provided between the pair of source/drain regions SD. The source/drain regions SD may contact opposing side surfaces of the channel structure 206 that are spaced apart from each other in the second direction D2.

The channel structure 206 may include semiconductor material(s) (e.g., Si, Ge, SiGe, GaP, GaAs, SiC, SiGeC and/or InP). In some embodiments, the channel structures 206 may include nanosheets that may have a thickness in a range from about 1 nanometers (nm) to 100 nm in the third direction D3 or may be a nanowire that may have a circular cross-section with a diameter in a range of from about 1 nm to 100 nm. When the channel structure 206 includes a nanosheet or nanowire, the gate structure 104 may extend around or at least partially surround the channel structure 206 on multiple sides.

Each of the source/drain regions SD may include a semiconductor layer (e.g., a silicon (Si) layer and/or a silicon germanium (SiGe) layer) and may additionally include dopants in the semiconductor layer. The gate insulator may include a single layer or multiple layers (e.g., a silicon oxide layer and/or a high-k dielectric material layer). For example, the high-k dielectric material layer may include Al₂O₃, HfO₂, ZrO₂, HfZrO₄, TiO₂, Sc₂O₃, Y₂O₃, La₂O₃, Lu₂O₃, Nb₂O₅ and/or Ta₂O₅.

The integrated circuit device 100 may include multiple gate structures 104 that extend (i.e., longitudinally) in the first direction D1 and are spaced apart from each other in the second direction D2. Each of the gate structures 104 may include a single layer or multiple layers. In some embodiments, each of the gate structures 104 may include a metal layer or material that includes, for example, tungsten (W), aluminum (Al), copper (Cu), molybdenum (Mo), cobalt (Co) and/or ruthenium (Ru), and may additionally include work function layer(s) (e.g., a TiN layer, a TaN layer, a TiAl layer, a TiC layer, a TiAlC layer, a TiAlN layer and/or a WN layer). In some embodiments, each of the gate structures 104 may include the same material(s).

In some embodiments, the transistor structure TS may be a three-dimensional (3D) field effect transistor (FET) such as a multi-bridge channel FET (MBCFET). In some embodiments, the transistor structure TS may have a structure different from that illustrated. For example, the transistor structure TS may be a gate-all-around FET (GAAFET) including a single channel structure or a fin-shaped FET (FinFET).

Source/drain contacts (not shown) may respectively contact the source/drain regions SD. The source/drain contacts may include a metal layer or material including, for example, W, Al, Cu, Mo, Co and/or Ru. Backside gate contact structures 210 (also referred to herein as backside gate contacts) may extend through the substrate 102 (in the third direction D3) from a second side S2 to contact the gate structures 104 on the first side S1, as described in greater detail below. The backside gate contacts 210 may respectively contact bottom portions or bottom surfaces 104b of the gate structures 104. The source/drain contacts and/or the backside gate contact structure 210 may include a metal layer or material including, for example, W, Al, Cu, Mo, Co and/or Ru.

As shown in greater detail in the cross-sectional view of FIG. 2A, the channel structures 206 and the gate structure 104 are provided on a first side S1 of the substrate. The integrated circuit device 100 further includes a backside gate contact structure 210 that is electrically connected to the gate structure 104 at a bottom portion or surface 104b. The backside gate contact structure 210 extends through the substrate 102 from a second side or backside S2 of the substrate 102 to contact the gate structure 104 on the first side or frontside S1 of the substrate 102. In some embodiments, the backside gate contact structure 210 may extend in the substrate 102 in a vertical (e.g., Z−) direction. The upper portion 210u of the backside gate contact structure 210 may not overlap the channel structures 206 in the third direction D3 (e.g., the vertical (Z−) direction), and may be formed in a self-aligned manner based on capping patterns 426 that are aligned with the channel structures 206 on the opposite side of the substrate 102, as described in greater detail below.

FIG. 2B is an enlarged cross-sectional view illustrating upper and lower contact structures of the backside gate contact structure of FIG. 2A. As shown in FIG. 2B, first and second channel structures 206a and 206b are spaced apart in a first horizontal (e.g., X-) direction D1 on the first side S1 of the substrate 102, and the gate structure 104 extends in the first horizontal direction D1 on the first side S1 of the substrate 102. A bottom portion 104 of the gate structure 104 extends between the first and second channel structures 206a and 206b. A device isolation pattern 208 is provided on the first side S1 of the substrate 102 between the first and second channel structures 206a and 206b. The backside gate contact structure 210 contacts the gate structure 104 between the first and second channel structures 206a and 206b. For example, the backside gate contact structure 210 may extend through the device isolation pattern 208 to contact the bottom portion 104b of the gate structure 104.

Still referring to FIG. 2B, the backside gate contact structure 210 includes a lower contact structure 210l and an upper contact structure 210u. The upper contact structure 210u may contact (e.g., may be directly on) the gate structure 104, and may extend between the lower contact structure 210l and the gate structure 104. The upper contact structure 210u and the lower contact structure 210l may be a monolithic or unitary structure that is formed from a same material (i.e., without structurally or visibly separate interfaces therebetween) in some embodiments. In some embodiments, the upper contact structure 210u may not overlap the channel structures 206 in the third direction D3, while the lower contact structure 210l may at least partially overlap the channel structures 206 in the third direction D3.

Respective side surfaces 210us, 210ls of the upper and lower contact structures 210u, 210l may be formed at different angles θ1, ƒ2, and thus, may have different slopes. For example, a first slope of the side surface 210us (e.g., having a first angle θ1) of the upper contact structure 210u may be less than a second slope of the side surface 210ls (e.g., having a second angle θ2) of the lower contact structure 210l, or vice versa. Also, the respective side surfaces 210us, 210ls of the upper and lower contact structures 210u, 210l may not be aligned, resulting in at least one step difference ST between the respective side surfaces 210us, 210ls of the upper and lower contact structures 210u, 210l. The step difference ST may be spaced apart from the device isolation pattern 208 by a spacing Sp in the third (e.g., Z) direction D3.

FIG. 2C is a cross-sectional view taken along line II-II of FIG. 1, illustrating an integrated circuit device 100′ including self-aligned backside gate contact structures according to some embodiments. As shown in FIG. 2C, the backside gate contact structure 210′ has an asymmetric shape, with a more significant misalignment (and thus, a more pronounced step difference ST) between the respective side surfaces 210us, 210ls of the upper and lower contact structures 210u ′, 210l ′. The embodiment of FIG. 2C is otherwise similar to that of FIG. 2A, and repeated description of similar elements are omitted for brevity.

As shown in FIGS. 2A and 2C, a backside power distribution network (BSPDN) structure 212 is provided on the second side S2 of the substrate 102, and the backside gate contact structure 210 (210′) electrically connects the BSPDN structure 212 to the gate structure 104. The BSPDN structure 212 may be provided on a lower surface of the backside gate contact 210 and a lower surface of the substrate 102. The BSPDN structure 212 may include a backside insulator 216 and one or more backside power rails 214 provided in the backside insulator 216. The backside power rail 214 may be electrically connected to lower contact structure 210l (210l ′) of the backside gate contact 210. The backside power rail 214 may include a metal layer or material including, for example, W, Al, Cu, Mo, Co and/or Ru.

The backside power rail 214 may be electrically connected to a power source with a predetermined voltage (e.g., a drain voltage or a source voltage). For example, the BSPDN structure 212 may include a power delivery network. The power delivery network may include a wiring network, which is used to deliver power (e.g., gate voltages) to the backside power rail 214. The gate structure 104 may be electrically connected to the power source through the backside gate contact 210 and the backside power rail 214. The backside gate contact 210 may be between the backside power rail 214 and the gate structure 104 in the third direction D3. In some embodiments, one or more conductive plugs may be provided between the backside gate contact 210 and the backside power rail 214. The backside gate contact 210 and the conductive plug may include the same materials. For example, the backside gate contact 210 and the conductive plug may be integrated in a monolithic or unitary structure, that is, a structure formed by the same process or the same series of processes without a structurally or visibly separate interfaces.

As used herein, the backside power rail 214 may refer to one or more conductive elements included in the BSPDN structure 212. For example, the backside power rail 214 may include a power rail, a conductive via plug, and/or a conductive wire included in the BSPDN structure 212. That is, while illustrated as including the backside power rail 214 and the backside insulator 216, it will be understood that the BSPDN structure 212 may include one or more conductive layers (e.g., metal layers) stacked in the third direction D3 that provide backside power delivery to the transistor structure TS. The conductive layers may be respectively included in insulating layers, and conductive via plugs (e.g., metal via plugs) may electrically connect the conductive layers to each other in the third direction D3. For example, although the backside insulator 216 is illustrated as a single layer, in some embodiments, the backside insulator 216 may include multiple layers stacked on the lower surface of the substrate 102. The conductive layers may include one or more conductive wires (e.g., metal wires). In some embodiments, an intervening structure may be provided between the substrate 102 and the BSPDN structure 212 and may separate the substrate 102 from the BSPDN structure 212. The BSPDN structure 212 may increase a power delivery efficiency in the integrated circuit device 100, reduce an area used for power delivery in the integrated circuit device 100, and/or improve a voltage drop (i.e., IR drop) in the integrated circuit device 100.

As described in greater detail below, the integrated circuit device 100 may further include gate placeholder elements (also referred to herein as placeholders) 530 that are formed in the substrate 102 (e.g., in the upper portion of the substrate 102). The placeholder 530 may be replaced with the upper contact structure 210u in the subsequent processes. The placeholder 530 may include a material different from the backside gate contact 210 and/or the substrate 102. The placeholder 530 may include, for example, a semiconductor material (e.g., Si or SiGe) and/or an insulating material (e.g., silicon oxide, silicon oxynitride, silicon nitride, silicon carbonitride, silicon boron nitride and/or a low-k material). In a process of replacing a silicon substrate or other semiconductor structure 320 with a backside insulating substrate 102 (e.g., including an oxide layer), a placeholder 530 is formed, and a final backside gate contact structure 210 is formed by replacing the placeholder 530 in a self-aligned manner and with a unique shape as shown in FIGS. 2A to 2C.

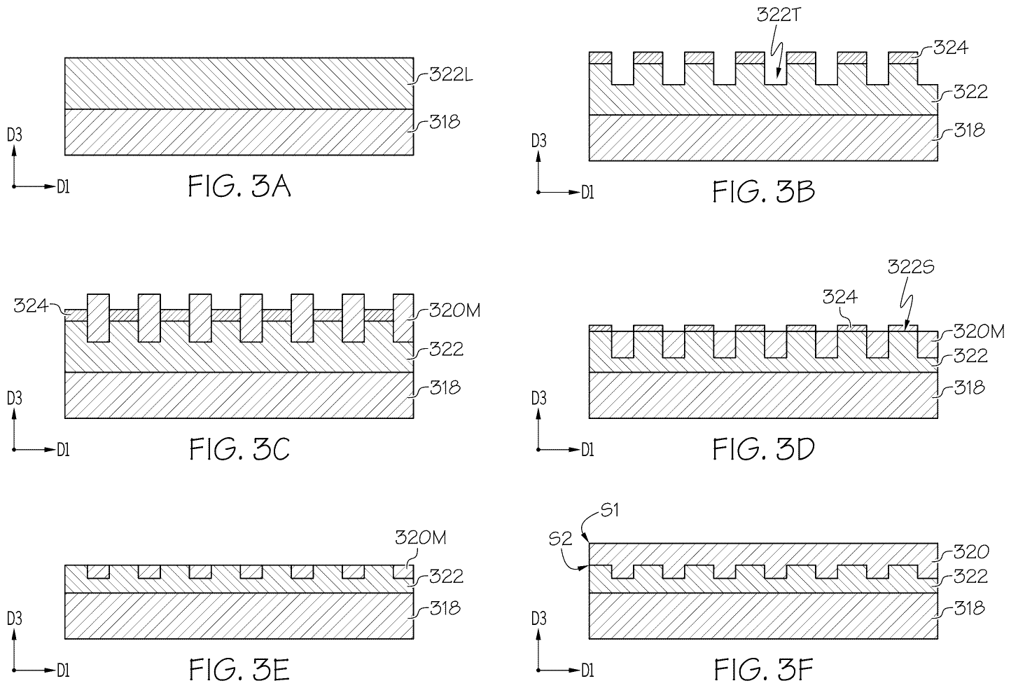

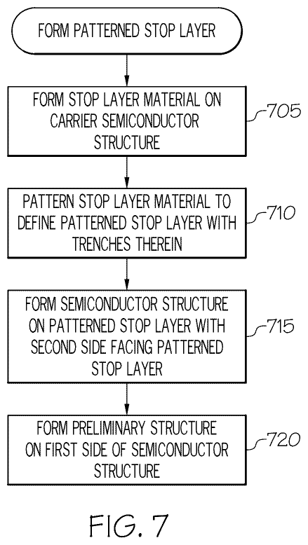

FIGS. 3A, 3B, 3C, 3D, 3E, and 3F are cross-sectional views and FIG. 7 is a flowchart illustrating methods of forming a patterned stop layer 322 for fabricating self-aligned backside gate contact structures 210 according to some embodiments. As shown in FIG. 3A, a stop layer material 322L is formed on a preliminary (e.g., a carrier) semiconductor structure 318 (at block 705). The stop layer material 322L and the carrier semiconductor structure 318 may be formed of different materials, e.g., semiconductor materials having etch selectivity to one another for selective etching processes as described herein. For example, the carrier semiconductor structure 318 may include silicon (Si), while the stop layer material 322L may include silicon germanium (SiGe).

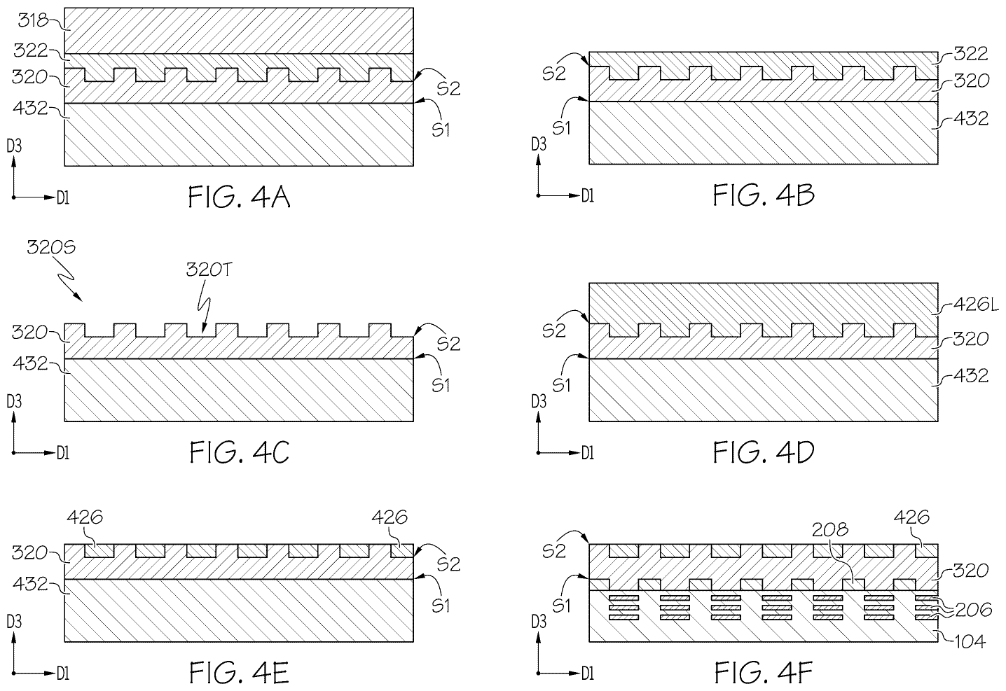

As shown in FIG. 3B, a stop layer mask pattern 324 (for example, an oxide mask pattern) is formed on the stop layer material 322L, and the stop layer material 322L is patterned to form a patterned stop layer 322 having plurality of trenches 322T therein on the carrier semiconductor structure 318 (at block 710). The stop layer 322 may provide a backside thinning stop layer for the operations shown in FIG. 4B. The stop layer mask pattern 324 used to form the patterned stop layer 322 may include a corresponding or complementary pattern as a channel mask pattern that is subsequently used to form channel structures 206 as described herein. For example, the stop layer mask pattern 324 and the channel mask pattern may include related patterns. That is, stop layer mask pattern 324 and the channel mask pattern (described below) may be based on complementary patterns, such that the locations for the mask patterns 324 between the trenches or recesses 322T in the stop layer 322 may correspond to the locations for the channel structures 206. For example, surfaces between each of the trenches 322T may overlap with the respective channel structure 206 in the third direction D3.

As shown in FIG. 3C, a semiconductor material 320M is formed in the trenches 322T in the patterned stop layer 322 (e.g., by epitaxial growth), and a planarization process (e.g., chemical mechanical polishing (CMP) process) is performed as shown in FIG. 3D such that surfaces 322S of the patterned stop layer 322 and the epitaxially grown semiconductor material are substantially coplanar. For example, a chemical mechanical polishing process may be performed such that that silicon germanium patterned stop layer 322 and the epitaxially grown silicon have substantially planar surfaces. As shown in FIG. 3E, remaining portions of the stop layer mask pattern 324 are removed, e.g., using a planarization or cleaning process. For example, remaining oxide materials of an oxide mask pattern 324 may be removed by a wet cleaning process.

As shown in FIG. 3F, the semiconductor material 320M may be epitaxially grown to form a semiconductor structure 320 with a second side S2 (e.g., a backside) on or facing the patterned stop layer 322 (at block 715). As described below, a preliminary semiconductor layer structure 432 for front-end-of-line (FEOL) structures may be subsequently formed on a first side S1 (e.g. a frontside) of the semiconductor structure, opposite the patterned stop layer 322 (at block 720).

In particular embodiments, a SiGe patterned stop layer 322 is formed using an oxide mask pattern 324 in FIG. 3B, including patterns (trenches or other recesses 322T) corresponding to that of the channel mask pattern (e.g., a nanosheet mask pattern) that is used to form the channel structures 206 in a subsequent process. After Si epitaxial growth 320M in the patterns or trenches 322T of the stop layer 322 in FIG. 3C, a CMP process is performed in FIG. 3D such that surfaces of the SiGe patterned stop layer 322 and the Si epitaxial layers 320M formed in the trenches 322T therein are substantially coplanar. The remaining portions of the oxide mask pattern 324 are removed by a wet cleaning process and/or further planarization in FIG. 3E, and Si is again epitaxially grown to form the semiconductor structure 320 with a first side S1 (or frontside) opposite the patterned stop layer in FIG.3F.

That is, a method of fabricating an integrated circuit device 100 includes patterning a stop layer material 322L to define a patterned stop layer 322 having plurality of trenches 322T therein that are spaced apart in a first direction, and forming a semiconductor structure 320 on the patterned stop layer 322. The semiconductor structure 320 includes a different material than the patterned stop layer 322, with a second side S2 thereof facing the patterned stop layer 322. Channel structures 206 may be subsequently formed spaced apart in the first direction on a first side S1 of the semiconductor structure 320 that is opposite the second side S2.

Since the patterned stop layer 322 is formed early in the fabrication process, the patterned stop layer 322 may have a high overlay value with the channel structures 206 to be formed in subsequent processes. The patterning locations (e.g., the trenches 322T) of the patterned stop layer 322 may thus correspond to the patterning locations of the channel structures 206, which may be used to form backside patterns (e.g., formed of silicon nitride (SiN); also referred to herein as capping patterns 426) and channel structures 206 that vertically overlap the capping patterns 426 on opposite sides of the semiconductor structure 320, thereby allowing for formation of self-aligned backside gate contact structures 210 as described below.

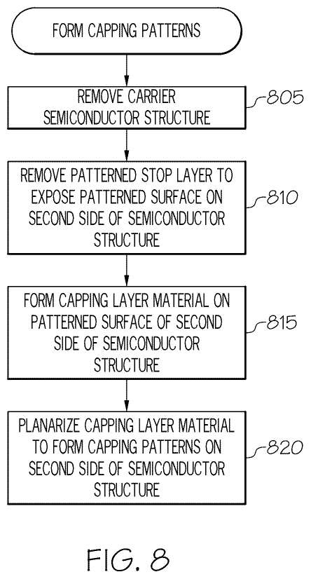

FIGS. 4A, 4B, 4C, 4D, 4E, and 4F are cross-sectional views and FIG. 8 is a flowchart illustrating methods of forming capping patterns 426 for fabricating self-aligned backside gate contact structures 210 according to some embodiments.

As shown in FIG. 4A, a preliminary semiconductor layer structure 432 (for front-end-of-line (FEOL) processing) is provided on the first side S1 (or frontside) of the semiconductor structure 320. In some embodiments, the preliminary semiconductor layer structure 432 may be bonded to the first side S1 of the semiconductor structure 320 in the process illustrated in FIG. 4A. In some embodiments, elements of the preliminary semiconductor layer structure 432 may be formed in (on) the preliminary semiconductor layer structure 432 after the preliminary semiconductor layer structure 432 is formed on (e.g., bonded to) the first side S1 of the semiconductor structure 320. In particular, front-end-of-line (FEOL) processes (including fabrication of the gate structures 104, shallow trench isolation (STI) or other device isolation patterns or layers 208, well regions, source/drain regions, and metal interconnection layers or structures) may be performed on the preliminary semiconductor layer structure 432, and channel structures 206 (e.g., nano sheet structures) are formed on a first side S1 (e.g. a front side) of a semiconductor structure 320. The semiconductor structure 320 may be turned over (inverted in the third direction D3) so that the carrier semiconductor structure 318 is upward facing.

As shown in FIG. 4B, a backside thinning operation is performed such that portions of the carrier semiconductor structure 318 on a second side S2 (i.e., a backside) of the semiconductor structure 320 are thinned or otherwise removed until a back surface of the patterned stop layer 322 is exposed (block 805). As used herein, the term “exposed” may be used to describe relationships between elements and/or certain intermediate processes in fabricating a completed integrated circuit device 100, but may not necessarily require exposure of the particular region, layer, structure or other element in the context of the completed device.

As shown in FIG. 4C, the patterned stop layer 322 is removed or stripped (for example, using a selective etching process) to expose a patterned surface 320S on the second side S2 of the semiconductor structure 320 (at block 810). The patterned surface 320S of the second side S2 of the semiconductor structure 320 may thereby include a plurality of trenches 320T or recesses therein, based on and corresponding to the trenches 322T in the patterned stop layer 322. The trenches 320T of the patterned surface 320S of the second side (or backside) S2 of the semiconductor structure 320 may vertically overlap (in the third direction D3) with the channel structures 206 on the first side S1 (or frontside) of the semiconductor structure 320.

As shown in FIG. 4D, a capping layer material 426L is deposited or otherwise formed on the patterned surface 320S of the second side S2 of the semiconductor structure 320 (at block 815). The capping layer material 426L may include or may be silicon nitride (SiN), silicon oxide (SiO), or other material that may be selectively etched with respect to materials of the semiconductor structure 320 and/or (subsequently formed) mask patterns or substrates 102. The capping layer material 426L may conformally extend on the patterned surface 320S of the second side S2 of the semiconductor structure 320, at least partially filling the trenches or recesses 320T therein.

As shown in FIG. 4E, a planarization process (such as a chemical mechanical polishing process) is performed to expose the surfaces of the semiconductor structure 320 (block 820). Portions of the capping layer material 426L remain in the trenches 320T in the second side S2 or backside of the semiconductor structure 320 to provide capping patterns 426.

As shown in greater detail in FIG. 4F, the channel structures 206 on the first side S1 of the semiconductor structure 320 may overlap (along a direction D3 (e.g., the Z-direction) perpendicular to the frontside or backside surface of the semiconductor structure 320, also referred to herein as vertical overlap) the trenches 320T of the patterned surface 320S on the second side S2 of the semiconductor structure 320. For example, opposing side surfaces of the channel structures 206 on the frontside S1 may be substantially aligned (along a direction D3 perpendicular to the frontside or backside surface of the semiconductor structure 320, also referred to herein as vertically aligned) with opposing sidewalls of the trenches 320T of the patterned surface 320S on the backside S2. The channel structures 206 on the first side S1 likewise vertically overlap the capping patterns 426 on the second side S2 or backside of the semiconductor structure 320 in the direction D3. For example, the capping patterns 426 may include opposing side surfaces that are substantially aligned with the opposing side surfaces of the channel structures 206 in the third direction D3 (e.g., the vertical or Z-direction).

That is, a method of fabricating an integrated circuit device 100 includes forming capping patterns 426 in trenches or recesses 320T of a patterned surface 320S on a second side S2 (or backside) of a semiconductor structure 320. The capping patterns 426 are spaced apart in a first direction on the second side S2 of the semiconductor structure 320, which is opposite a first side S1 (or frontside). The channel structures 206 are formed spaced apart in the first direction on the first side S1 of a semiconductor structure 320. A gate structure 104 extends in the first direction on the first side S1 of the semiconductor structure 320, with a bottom portion 104b of the gate structure 104 extending between first and second channel structures 206a and 206b among the channel structures 206. The channel structures 206 on the first side S1 of the semiconductor structure 320 may vertically overlap with the trenches or recesses 320T of the patterned surface 320S on the second side S2, such that respective capping patterns 426 formed in the trenches 320T on the second side S2 vertically overlap respective channel structures 206.

In particular embodiments, a backside thinning step is performed in FIG. 4B to reveal a back surface of an SiGe patterned stop layer 322, and a patterned Si surface 320S is revealed after stripping or removal of the SiGe patterned stop layer 322 in FIG. 4C. Trenches or other recesses 320T in the patterned Si surface 320S (provided by removal of the SiGe patterned stop layer 322) are filled with a SiN capping layer material 426L in FIG. 4D, followed by a CMP process using the Si surface 320S as a stop layer in FIG. 4E, to form SiN capping patterns 426 in the trenches 320T on the backside S1 of the semiconductor structure 320. Channel structures 206 (e.g., nanosheet structures) are formed in locations or positions on the frontside S1 of the semiconductor structure 320 that are aligned to the locations or positions of the capping patterns 426 on the backside S2. That is, the capping patterns 426 on the second side S2 or backside of the semiconductor structure 320 vertically overlap (and may include opposing sidewalls that are vertically aligned with) the channel structures 206 on the first side S1 or front side of the semiconductor structure 320. The capping patterns 426 are used to form self-aligned gate placeholder elements 530 (which are replaced with backside gate contact structures 210) in subsequent processes, such that the backside gate contact structures 210 contact bottom portions 104b of the gate structure 104 and are aligned based on the capping patterns 426.

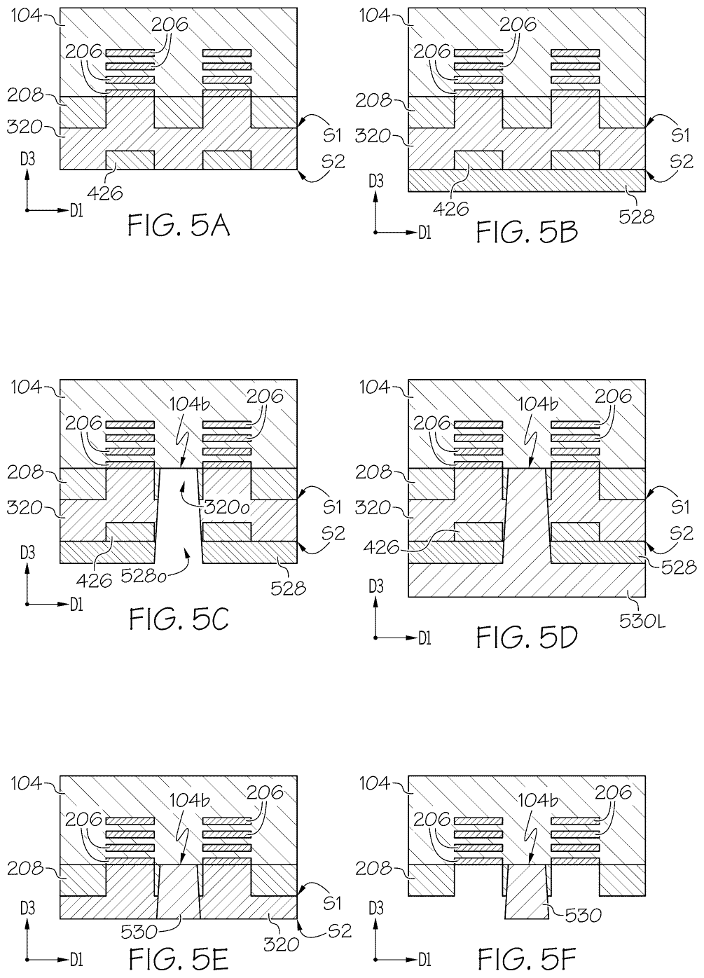

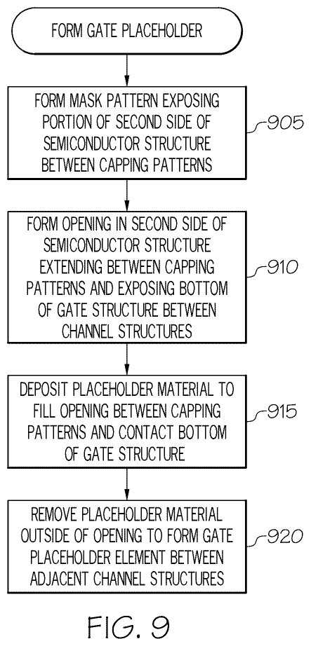

FIGS. 5A, 5B, 5C, 5D, 5E, and 5F are cross-sectional views and FIG. 9 is a flowchart illustrating methods of forming gate placeholder elements 530 for fabricating self-aligned backside gate contact structures 210 according to some embodiments.

As shown in FIG. 5A, the capping patterns 426 on the second or backside S2 of the semiconductor structure 320 are self-aligned with and vertically overlap the channel structures 206 on the first or front side S1 of the semiconductor structure 320. As shown in FIG. 5B, a hard mask layer 528 is formed on the second or backside of the semiconductor structure 320. The hard mask layer 528 may include or may be formed of a material (for example, an oxide-based material) that differs in material composition from (and thus has etch selectivity to) the material of the capping patterns 426 (for example, a nitride-based material).

As shown in FIG. 5C, the hard mask layer 528 is patterned (e.g., lithographically) to define mask openings 5280 therein (block 905). The mask openings 5280 in the patterned hard mask layer 528 expose portions of the second side S2 or backside of the semiconductor structure 320 that are between adjacent capping patterns 426. The exposed portions of the second side S2 or backside of the semiconductor structure 320 are selectively etched using the patterned hard mask layer 528 as an etching mask to form openings 3200 in the second side S2 of the semiconductor structure 320 that expose a bottom surface or portion 104b of the gate structures 104 between adjacent channel structures 206 (block 910). The etching process may be selective to the material of the capping patterns 426, such that the openings 3200 (and the bottom portions 104b of the gate structures 104 exposed thereby) are aligned by and extend between adjacent capping patterns 426 (and between the channel structures 206 that vertically overlap the adjacent capping patterns 426).

As shown in FIG. 5D, a placeholder material 530L is deposited to fill the openings 3200 in the portions of the backside S2 of the semiconductor structure 320 (and the corresponding mask openings 5280 in the patterned hard mask layer 528) such as the placeholder material 530L contacts the bottom surfaces or portions 104b of the gate structures 104 between adjacent channel structures 206 (block 915). As shown in FIG. 5E, the portions of the placeholder material 530L that extends outside the openings 3200 (as well as the patterned hard mask layer 528 and the capping patterns 426) are removed such that portions of the placeholder material 530L that contact the bottom surfaces or portions 104b of the gate structures 104 between adjacent channel structures 206 remain as gate placeholder elements 530 (block 920). For example, the portions of the placeholder material 530L outside the openings 3200, the patterned hard mask layer 528, and the capping patterns 426 may be removed by chemical mechanical polishing process using the semiconductor structure 320 as a stop layer. As shown in FIG. 5F, the semiconductor structure 320 are selectively removed from the backside S2 (for example, using a wet cleaning process that is selective to the material of the semiconductor structure 320) to expose device isolation patterns 208 between adjacent channel structures 206, and such that the gate placeholder elements 530 remain in contact with the bottom portion 104b of the gate structure 104.

In particular embodiments, using a self-aligned SiN capping pattern 426, a backside gate contact structure 210 that directly contacts a bottom portion 104b of a gate structure 104 between adjacent channel structures 206 can be more easily and more accurately formed. However, as the Si or other semiconductor structure 320 may be replaced with a dielectric substrate 102 (e.g., an oxide substrate, such as SiO2), a gate placeholder element 530 is formed first. An etch process is carried out between the nanosheets or other channel structures 206, and an etched space is filled with silicon nitride followed by CMP to form the gate placeholder element 530.

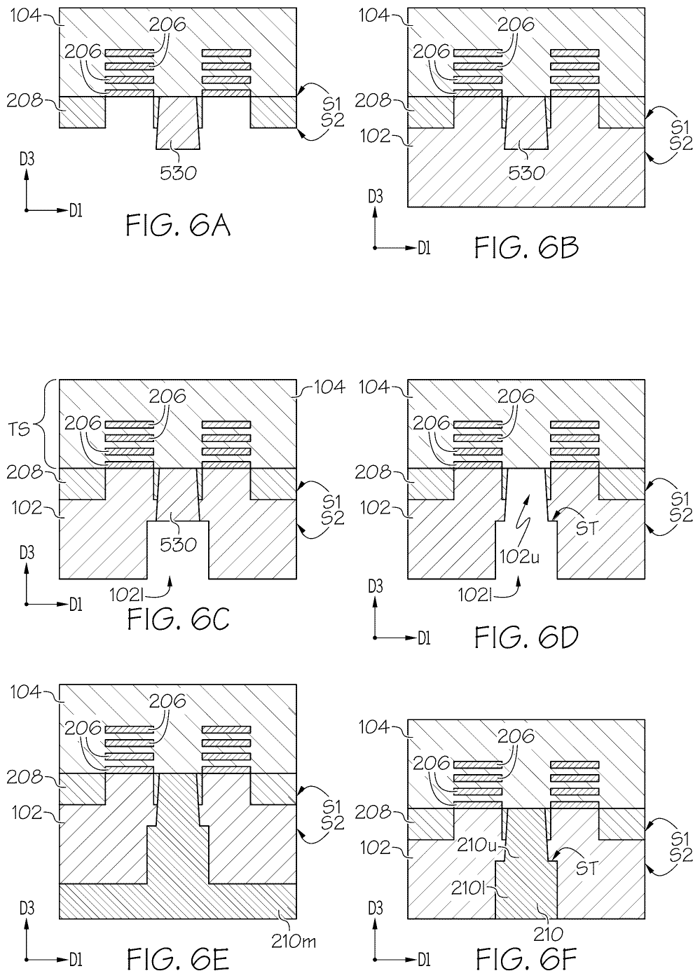

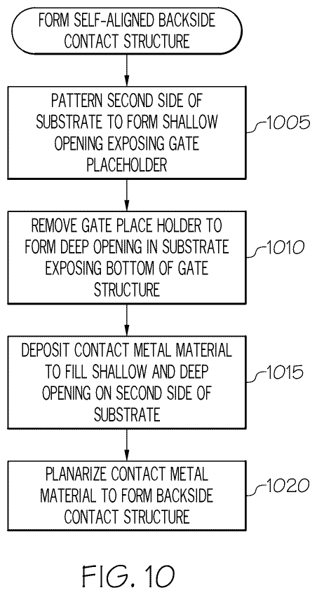

FIGS. 6A, 6B, 6C, 6D, 6E, and 6F are cross-sectional views and FIG. 10 is a flowchart illustrating methods of forming self-aligned backside gate contact structures 210 using the gate placeholder elements 530 according to some embodiments.

As shown in FIG. 6A, the gate placeholder element 530 extends from the second side S2 or backside (of the removed semiconductor structure 320) to directly contact a bottom portion 104b of a gate structure 104 between adjacent channel structures 206. The gate placeholder elements 530 extend through portions of the device isolation patterns 208 (e.g., the STI layer), with remaining portions of the device isolation patterns 208 extending along portions of the side surfaces of the gate placeholder elements 530. As shown in FIG. 6B, a dielectric or insulating material (e.g., an oxide material) is formed on the second side S2 or backside of the removed semiconductor structure 320 to form a backside insulating layer or substrate 102. The backside insulating layer or substrate 102 may be formed on a lower surface of the channel structures 206. The substrate 102 may have a first side (or frontside) S1 and a second side (or backside) S2. The frontside S1 may face the transistor structure TS, and the backside S2 may be opposite to the frontside S1 in the third direction D3.

As shown in FIG. 6C, the backside S2 of the substrate 102 is patterned (e.g., lithographically) to define first or shallower openings 1021l therein that expose the gate placeholder elements 530 between adjacent capping patterns 426 (block 1005). The shallower openings 1021l in the substrate 102 (which expose the gate placeholder elements 530) may define the shape of a lower portion of the backside gate contact structure 210 (also referred to as a lower contact structure 210l) that is formed in subsequent operations. As shown in FIG. 6D, the gate placeholder elements 530 are selectively removed, for example, using a selective wet etching process, thereby forming second or deeper openings 1021u in the substrate 102 that expose the bottom portions 104b of the gate structures 104 between adjacent channel structures 206 (block 1010). The etching process may be selective to the material of the device isolation patterns 208, such that remaining portions of the device isolation patterns 208 extend along portions of the side surfaces of the deeper openings 1021u in the substrate 102. The deeper openings 1021u in the substrate 102 (which expose the bottom portions 104b of the gate structure) may define the shape of an upper portion of the backside gate contact structure 210 (also referred to as a upper contact structure 210u) that is formed in subsequent operations. Respective sidewalls of the deeper openings 1021u may have different slopes than respective sidewalls of the shallower openings 1021l. In the example of FIG. 6D, a step difference ST is defined between the respective sidewalls of the deeper opening 1021u (formed by removing the gate placeholder 530) and the shallower opening 1021l (formed by patterning the substrate 102 to expose the gate placeholder 530). The cross-sectional profiles of the shallower opening 1021l and the deeper opening 1021u may vary. For example, while illustrated as being narrower than the shallower openings 1021l, the deeper openings 1021u may be wider (along the first direction D1 or the second direction D2 parallel to the backside S2 of the substrate 102) than the shallower openings 1021l in some embodiments.

As shown in FIG. 6E, a contact metal material is deposited on the second side S2 or backside S2 of the substrate 102, filling the shallow and deep openings 1021l and 1021u therein to contact the bottom portions 104b of the gate structures 104 exposed by the openings (block 1015). As shown in FIG. 6F, a planarization process (e.g., CMP) using the material of the substrate 102 (e.g., the oxide material) as a stop layer is performed to form the backside gate contact structure 210 (block 1020). A BSPDN structure 212 (including a backside power rail 214, backside insulator 216, and associated conductive plugs) may be formed to arrive at the integrated circuit device 100 shown in FIGS. 2A-2C, with the backside gate contact structure 210 providing electrical connection between the gate structure 104 and the BSPDN structure 212.

As noted with reference to FIGS. 2A-2C, the backside gate contact structure 210 includes a lower contact structure 210l and an upper contact structure 210u, where the upper contact structure 210u contacts the gate structure 104 and extends between the lower contact structure 210l and the gate structure 104. Because the upper contact structure 210u and the lower contact structure 210l of the backside gate contact structure 210 are formed using separate fabrication operations or processing steps, respective side surfaces 210us, 210ls of the upper and lower contact structures 210u and 210l can be formed at different angles, and thus, may have different slopes. For example, a side surface 210us of the upper contact structure 210u may have a first slope that is less than a second slope of the side surface 210ls of the lower contact structure 210l, or vice versa. Also, because the upper contact structure 210u in lower contact structure 210l are formed in separate fabrication operations or processing steps, the respective side surfaces 210us, 210ls of the upper and lower contact structures 210u and 210l may not be aligned, resulting in at least one step difference ST between the respective side surfaces 210us, 210ls of the upper and lower contact structures 210u and 210l. That is, since the gate placeholder elements 530 are selectively formed at a gate contact positions only, and as the gate placeholder elements 530 are formed with a unique shape, the upper portions of the backside gate contact structures 210 are formed with shapes that correspond to the shape of the gate placeholder elements 530, while the lower portions of the backside gate contact structures 210 are formed with different shapes that correspond to the shallower opening 1021l in the substrate 102.

Unless otherwise defined, all terms used herein have the same meaning as commonly understood by one of ordinary skill in the art. Further, all terms should be interpreted as having a meaning that is consistent with their meaning in the context of the relevant art and this disclosure and will not be interpreted in an idealized or overly formal sense unless expressly so defined herein.

In the description above, each example embodiment is described with reference to regions of particular conductivity types. It will be appreciated that opposite conductivity type devices may be formed by simply reversing the conductivity of the n-type and p-type layers in each of the above embodiments. Thus, it will be appreciated that the present invention covers both n-channel and p-channel devices for each different device structure.

The terminology used herein is for the purpose of describing particular embodiments only and is not intended to be limiting of embodiments. The singular forms “a,” “an,” and “the” are intended to include the plural forms as well, unless the context clearly indicates otherwise. The terms “comprises,” “comprising,” “includes” and/or “including” specify the presence of stated features, steps, operations, elements and/or components, but do not preclude the presence or addition of one or more other features, steps, operations, elements, components and/or groups thereof.

It will be understood that, although the terms “first,” “second,” etc. are used throughout this specification to describe various elements, these elements should not be limited by these terms. These terms are only used to distinguish one element from another. For example, a first element could be termed a second element, and, similarly, a second element could be termed a first element, without departing from the scope of the present invention. The term “and/or” includes any and all combinations of one or more of the associated listed items.

The terms “surround” or “cover” or “fill” as may be used herein may not require completely surrounding or covering or filling the described elements or layers, but may, for example, refer to partially surrounding or covering or filling the described elements or layers. Components or layers described with reference to “overlap” in a particular direction may be at least partially obstructed by one another when viewed along a line extending in the particular direction or in a plane perpendicular to the particular direction.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. The term “connected” may include physical and/or electrical connection.

Spatially relative terms such as “below” or “above” or “upper” or “lower” or “top” or “bottom” or “side” may be used herein to describe a relationship of one element, layer or region to another element, layer or region based on a frame of reference (e.g., a substrate), as illustrated in the figures. It will be understood that these terms are intended to encompass different orientations of the device in addition to the orientation depicted in the figures.

Example embodiments are described herein with reference to the accompanying drawings, which may include cross-section illustrations that are schematic illustrations of idealized embodiments (and intermediate structures). Many different forms and embodiments are possible without deviating from the teachings of this disclosure. Accordingly, the disclosure should not be construed as limited to the example embodiments set forth herein. As such, it will be understood by those of ordinary skill in the art that various changes in form and details may be made therein without departing from the spirit and scope as defined herein. In the drawings, the sizes and relative sizes of layers and regions may be exaggerated for clarity. Additionally, variations from the shapes of the illustrations as a result, for example, of manufacturing techniques and/or tolerances, are to be expected.

Embodiments of the invention are also described with reference to a fabrication operations and flowchart diagrams. It will be appreciated that the steps shown in the fabrication operations and flowchart diagrams need not be performed in the order shown.

The above-disclosed subject matter is to be considered illustrative, and not restrictive, and the appended claims are intended to cover all such modifications, enhancements, and other embodiments, which fall within the scope of the disclosure. Thus, to the maximum extent allowed by law, the scope is to be determined by the broadest permissible interpretation of the following claims and their equivalents, and shall not be restricted or limited by the foregoing detailed description.

1. A semiconductor device comprising:
first and second channel structures that are spaced apart in a first direction;
a gate structure that extends in the first direction, wherein a bottom portion of the gate structure extends between the first and second channel structures; and
a backside gate contact structure that is electrically connected to the bottom portion of the gate structure,
wherein the backside gate contact structure comprises a lower contact structure and an upper contact structure between the lower contact structure and the gate structure, and respective side surfaces of the upper contact structure and the lower contact structure have different slopes.

2. The semiconductor device of claim 1, wherein the respective side surfaces of the upper contact structure and the lower contact structure define a step difference therebetween.

3. The semiconductor device of claim 2, wherein a first slope of the side surface of the upper contact structure is less than a second slope of the side surface of the lower contact structure.

4. The semiconductor device of claim 2, further comprising:
a substrate including the first and second channel structures and the gate structure on a first side thereof,
wherein the backside gate contact structure extends into the substrate from a second side thereof that is opposite the first side to contact the gate structure.

5. The semiconductor device of claim 4, further comprising:
an isolation pattern on the first side of the substrate between the first and second channel structures,
wherein the backside gate contact structure extends through the isolation pattern to contact the gate structure, and wherein the step difference is spaced apart from the isolation pattern in a second direction that is perpendicular to the first direction.

6. The semiconductor device of claim 4, further comprising:
a backside power distribution network structure on the second side of the substrate, wherein the backside gate contact structure electrically connects the backside power distribution network structure to the gate structure.

7. The semiconductor device of claim 4, wherein each of the first and second channel structures comprises a plurality of nanosheet structures that are stacked on the first side of the substrate.

8. A method of fabricating a semiconductor device, the method comprising:
forming channel structures that are spaced apart in a first direction on a first side of a semiconductor structure, wherein a bottom portion of a gate structure extends between first and second channel structures among the channel structures on the first side of the semiconductor structure;
forming capping patterns that are spaced apart in the first direction on a second side of a semiconductor structure that is opposite the first side, wherein first and second capping patterns among the capping patterns vertically overlap the first and second channel structures, respectively; and
forming a backside gate contact structure that contacts the bottom portion of the gate structure and is aligned based on the first and second capping patterns.

9. The method of claim 8, wherein opposing side surfaces of the first and second channel structures are substantially aligned with opposing side surfaces of the first and second capping patterns, respectively, in a second direction that is perpendicular to the first direction.

10. The method of claim 9, wherein forming the backside gate contact structure comprises:
forming a gate placeholder element that extends into the second side of the semiconductor structure between the first and second capping patterns and contacts the bottom portion of the gate structure between the first and second channel structures.

11. The method of claim 10, wherein forming the gate placeholder element comprises:
forming an opening in the second side of the semiconductor structure that extends between the first and second capping patterns and exposes the bottom portion of the gate structure between the first and second channel structures; and
forming the gate placeholder element in the opening.

12. The method of claim 10, wherein forming the backside gate contact structure further comprises:
removing portions of the semiconductor structure and the capping patterns thereon to expose the gate placeholder element between the first and second channel structures;
forming a substrate on the gate placeholder element and the channel structures, wherein the channel structures are on a first side of the substrate;
patterning a second side of the substrate that is opposite the first side to form a first opening therein that exposes the gate placeholder element; and
replacing the gate placeholder element with the backside gate contact structure.

13. The method of claim 12, wherein replacing the gate placeholder element comprises:
removing the gate placeholder element to form a second opening in the substrate that is coupled to the first opening and exposes the bottom portion of the gate structure between the first and second channel structures; and
forming the backside gate contact structure in the first and second openings.

14. The method of claim 13, wherein respective side surfaces of the first opening and the second opening have different slopes, and wherein the backside gate contact structure comprises a lower contact structure in the first opening and an upper contact structure in the second opening between the lower contact structure and the gate structure.

15. The method of claim 14, wherein the respective side surfaces of the first opening and the second opening define a step difference therebetween.

16. (canceled)

17. The method of claim 8, wherein forming the capping patterns comprises:
patterning a stop layer material that is different from a material of the semiconductor structure to define a patterned stop layer having plurality of first trenches therein that are spaced apart in the first direction;
forming the semiconductor structure on the patterned stop layer;
removing the patterned stop layer to expose a patterned surface on the second side of the semiconductor structure having a plurality of second trenches therein; and
forming the capping patterns in the second trenches in the patterned surface on the second side of the semiconductor structure.

18. A method of fabricating a semiconductor device, the method comprising:
patterning a stop layer material to define a patterned stop layer having plurality of first trenches therein that are spaced apart in a first direction;
forming a semiconductor structure on the patterned stop layer, the semiconductor structure comprising a different material than the patterned stop layer and having a second side thereof facing the patterned stop layer;
forming channel structures that are spaced apart in the first direction on a first side of the semiconductor structure that is opposite the second side; and
removing the patterned stop layer to expose a patterned surface having a plurality of second trenches therein on the second side of the semiconductor structure,
wherein the channel structures vertically overlap the second trenches in the patterned surface on the second side of the semiconductor structure.

19. The method of claim 18, wherein opposing side surfaces of the channel structures are substantially aligned with opposing sidewalls of the second trenches in the patterned surface, respectively, in a second direction that is perpendicular to the first direction.

20. The method of claim 19, further comprising:
forming capping patterns in the second trenches in the patterned surface on the second side of the semiconductor structure, wherein opposing side surfaces of the capping patterns are substantially aligned with opposing side surfaces of the channel structures, respectively.

21. The method of claim 20, further comprising:
forming a gate structure that extends in the first direction on the first side of the semiconductor structure, wherein a bottom portion of the gate structure extends between first and second channel structures among the channel structures;
forming a backside gate contact structure that contacts the bottom portion of the gate structure and is aligned based on first and second capping patterns among the capping patterns.

22.-28. (canceled)
